(19) United States
(12) Patent Application Publication
(10) Pub. No.: US 2019/0140460 A1
(43) Pub. Date: May 9, 2019

(54) CHARGING DEVICE, CHARGING CIRCUIT, AND CHARGING METHOD FOR BATTERIES IN SERIES

(71) Applicant: CHANGZHOU JWEI INTELLIGENT TECHNOLOGY CO., LTD., Changzhou (CN)

(72) Inventor: WEI-HUA QIU, ChangZhou (CN)

(21) Appl. No.: 16/240,809

(22) Filed: Jan. 7, 2019

Related U.S. Application Data
(63) Continuation-in-part of application No. PCT/CN2017/091478, filed on Jul. 3, 2017.

(30) Foreign Application Priority Data
Jul. 8, 2016 (CN) 201610537459.4

(51) Int. Cl. H02J 7/00; H01M 10/44; H01M 10/48; G01R 19/165; G01R 31/36; H01M 10/42

(52) U.S. Cl. CPC H02J 7/0026; H01M 10/441; H01M 10/482; H01M 2010/4271; G01R 31/3646; H01M 10/425; G01R 19/16542

(57) ABSTRACT

A charging circuit and device for charging batteries in series includes a controller, a first voltage detecting assembly, and a switching assembly. The first voltage detecting assembly electrically connects to a battery pack and the controller, and detects and transmits the voltage of each call of the battery pack. The battery pack includes at least two cells connected in series. The switching assembly includes switches corresponding to each cell. When a voltage of a cell reaches a predetermined value, the controller controls the governing switch to stop charging the cell. The charging circuit and device have simple structure, low cost, and high reliability and safety. A method for charging using the circuit and device is also presented.

### FIELD

The present disclosure relates to battery charging.

### BACKGROUND

Charging multiple battery cells in series can be problematic. Usually, battery packs made up of batteries in series are charged using a series charging circuit, and current series charging circuits are designed for series of batteries with two or three cells.

Thus, there is room for improvement within the art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views.

FIG. 1 is a block diagram of a first embodiment of a charging circuit which can be used with a battery pack.

FIG. 2 is a block diagram of a second embodiment of a charging circuit which can be used with the battery pack.

FIG. 3 is a block diagram of a third embodiment of a charging circuit which can be used with the battery pack.

FIG. 4 is a circuit diagram of a fourth embodiment of a charging circuit which can be used with the battery pack.

### DETAILED DESCRIPTION

In order to make the above-mentioned objects, features and advantages of the present implementation more obvious, a detailed description of specific embodiments of the present implementation will be described in detail with reference to the accompanying drawings. A number of details are set forth in the following description so as to fully understand the present implementation. However, the present implementation can be implemented in many other ways different from those described herein, and those skilled in the art can make similar improvements without violating the contents of the present implementation. Therefore, the present implementation is not to be considered as limiting the scope of the embodiments described herein.

Several definitions that apply throughout this disclosure will now be presented.

Unless otherwise defined, all technical and scientific terms used herein have the same meaning as commonly understood by one skilled in the art. The terms used in a specification of the present implementation herein are only for describing specific embodiments, and are not intended to limit the present implementation. The terms “and/or” used herein includes any and all combinations of one or more of associated listed items.

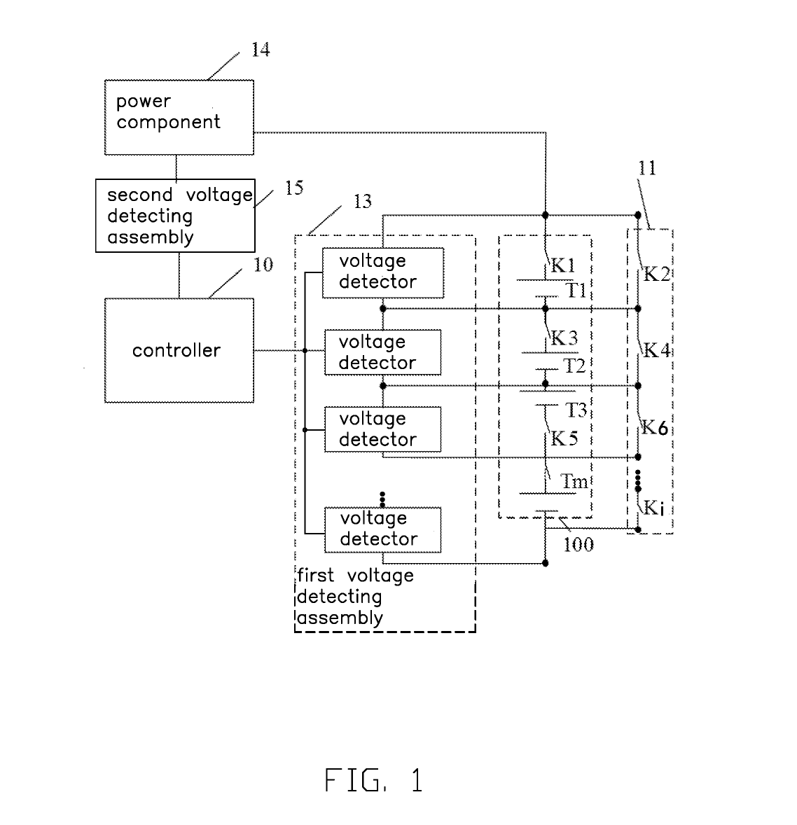

FIG. 1 shows a block diagram of a first embodiment of a charging circuit. The charging circuit is used for reliably and safely charging a battery pack 100 composed of at least two batteries in series. The charging circuit has a simple structure and a low cost. Referring to FIG. 1, the charging circuit includes a controller 10, a switching assembly 11, and a first voltage detecting assembly 13.

Specifically, the battery pack 100 includes a plurality of battery cells T1-Tm, which are followed by a first battery cell, a second battery cell to an mth battery cell, connected in series with each other.

The first voltage detecting assembly 13 is electrically connected to the battery pack 100 and the controller 10 for detecting a voltage of each battery cell in the battery pack 100. The detected voltage is passed to the controller 10. The voltage of each battery cell refers to the voltage difference between the positive and negative electrodes of the battery, which is the voltage drop of each battery, and the voltage of the entire battery pack 100 is the sum of the voltages of the individual batteries. As shown in FIG. 1, the first voltage detecting assembly 13 can be a plurality of voltage detectors having the same number of batteries in the battery pack 100, and each voltage detector is electrically connected to positive and negative poles of each battery. Each voltage detector is configured to detect a voltage of each battery in real-time.

The switching assembly 11 includes a plurality of switches corresponding to each of the battery cells of the battery pack 100. The switches include a first switch and a second switch. A pole of the first switch is connected to a pole of the corresponding battery, another pole of the first switch is connected to a pole of the second switch, and the other pole of the second switch is connected to the other pole of the corresponding battery. This description is only an example of an implementation where there is a first switch and the second switch. In other implementations, the switches of the switching assembly 11 may include more switches in series with the first switch or in series with the second switch. Additionally, the first switch and the second switch can be N-Metal-Oxide-Semiconductor (NMOS) or positive channel Metal Oxide Semiconductor (PMOS) switches.

The controller 10 is electrically connected to the first voltage detecting assembly 13, and configured to control a switch corresponding to a battery to stop charging the battery when the voltage of the battery detected by the first voltage detecting assembly 13 reaches a predetermined threshold value. The predetermined threshold value is a voltage value when the battery is fully charged. In actual implementation, if different batteries in the battery pack 100 have different voltage values when they are fully charged, each battery corresponds to its own predetermined threshold value. Therefore, when the controller 10 receives voltage values from the first voltage detecting assembly 13, the voltage value of each battery is compared with its own predetermined threshold value. If the voltage value of the battery reaches its predetermined threshold value, the switch corresponding to that battery is controlled to stop charging the battery.

Alternatively, when the voltage value of a certain battery reaches its predetermined threshold value, the first switch corresponding to the battery is disconnected and the second switch is connected, so that the charged battery can be bypassed and other batteries can be directly charged. Additionally, by setting the first switch in series with the battery, there is no problem such as short circuiting of the battery after the second switch is connected. When the voltage value of the certain battery has not reached the predetermined threshold value, the battery needs to be charged. Accordingly, the first switch corresponding to the battery to be charged is connected, and the second switch is disconnected, so that the external charging current can flow through the battery behind the first switch for charging the battery corresponding to the switch.

For example, for switches K1, K2, . . . , Ki, if the switch K1 is connected and the switch K2 is disconnected, the first battery T1 in battery pack 100 can be charged, and if the switch K1 is disconnected and the switch K2 is connected, the first battery T1 in battery pack 100 cannot be charged. K1 is the first switch corresponding to the first battery T1, K2 is the second switch corresponding to the first battery T1. Similarly, charging of other batteries in battery pack 100 can be controlled by corresponding switches. Therefore, by switching the switches K1, K2, . . . , Ki in the switching assembly 11, the charging circuits of the plurality of batteries in battery pack 100 can be charged to any number of batteries, for example the number of batteries may be one, two, three, or even more, i represents the number of the switches, i>2n where i is an integer.

In the illustrated embodiment, when each battery in the battery pack 100 is fully charged, to simplify processing, the charging circuit may include a driving circuit. The external power source can be turned off by the driving circuit to stop charging the battery pack 100. The driving circuit may include a driver and a main control switch. One terminal of the driver is connected to the controller 10, the other terminal of the driver is connected to a terminal of the main control switch, and the other terminal of the main control switch is electrically connected to the battery pack 100. The driver can be a Pulse-Width Modulation (PWM) driver, and the terminal of the driver electrically connected to the controller 10 can be electrically connected to an external charging interface (not shown in FIG. 1).

Each battery in series of the battery pack 100 will have a voltage signal supplied to the controller 10. The controller 10 determines whether the battery is fully charged by the voltage signal. If the battery is determined to be fully charged, the controller 10 will provide a control signal to the PWM driver to enable the PWM driver to stop the charging mode through the main control switch to stop the charging process of the battery, thereby preventing battery overcharging and improving the safety and reliability of the charging process.

The main control switch includes an inductor (not shown in FIG. 1), a diode (not shown in FIG. 1), a triode (not shown in FIG. 1), and a first capacitor (not shown in FIG. 1). A terminal of the inductor is connected to the driver, the other terminal of the inductor is connected to the anode of the diode, and the cathode of the diode is grounded through the first capacitor. The cathode of the diode is connected to a terminal of the battery pack 100. The base of the triode is electrically connected to the driver, the emitter of the triode is grounded, and the collector of the triode is connected to the anode of the diode.

Alternatively, the driving circuit may further include a power component 14 and a second voltage detecting assembly 15 for detecting the voltage of the power component 14. The second voltage detecting assembly 15 is electrically connected to the controller 10, and the second voltage detecting assembly 15 passes a detected voltage value of the power component 14 back to the controller 10. When the controller 10 detects the voltage value reaching a second predetermined threshold value, the charging current flowing through the power component 14 is excessive. To ensure safely charging the battery pack 100, the controller 10 can stop the external power source to stop charging the battery pack 100. The above exemplary implementation only consider the controller 10 detecting the voltage value returned by the second voltage detecting assembly 15. In other implementations, the controller 10 can calculate a current value flowing through the power component 14 based on the resistance value of the power component 14 and the received voltage value. The controller 10 stops charging the battery pack 100 when the electrical current value exceeds a predetermined current value. The predetermined current value is a maximum charging current, usually, the predetermined current value is a default current value of the system.

A terminal of the power component 14 is connected to a charging interface, another terminal of the power component 14 is connected to the inductor, and the second voltage detecting assembly 15 connects the two terminals of the power component 14. In an implementation, the power component 14 can be a resistor.

In the first embodiment, the charging circuit for a battery pack containing batteries in series detects the voltage of each battery in the battery pack 100 through the first voltage detecting assembly 13. When the voltage of any battery reaches a predetermined threshold value, the battery's corresponding switch stops charging the battery, thereby preventing overcharging or overcurrent, improving the safety and reliability of the charging process. Therefore, charging multiple batteries becomes reliable and safe, while the circuit structure used is simple and low cost.

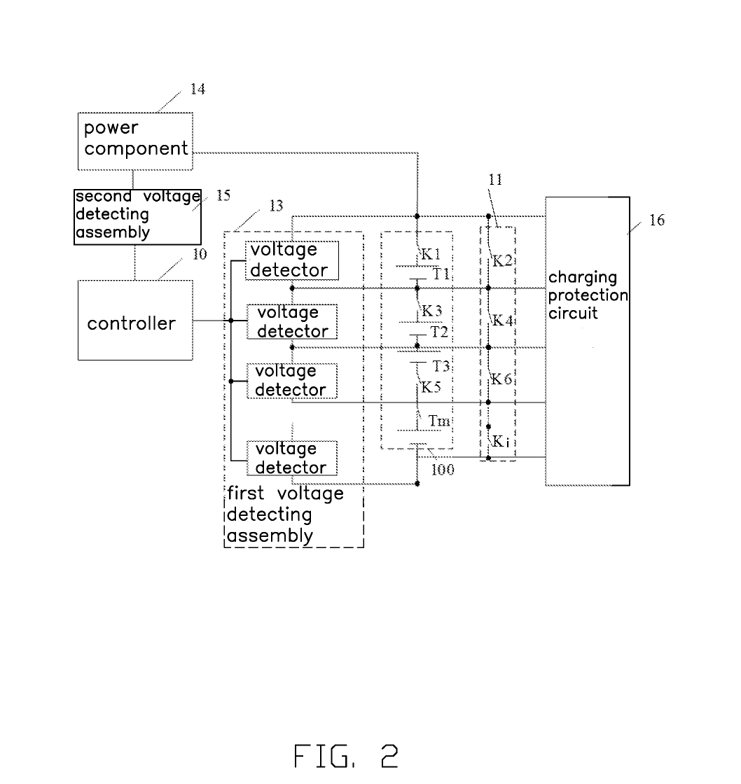

FIG. 2 shows a block diagram of a second embodiment of a charging circuit. FIG. 2 differs from FIG. 1 in that the charging circuit of FIG. 2 further includes a charging protection circuit 16.

Specifically, the charging protection circuit 16 electrically connects to the controller 10 and the battery pack 100. The charging protection circuit 16 is configured to send a control signal to the controller 10 when the battery pack fails. The charging protection circuit 16 detects the voltage of each battery in the battery pack 100. When the detected voltage of each battery exceeds the preset voltage, and the battery is fully charged, a control signal is sent to the controller 10. In one embodiment, the controller 10 is further configured to provide a cut-off signal to the driver when the control signal is sent by the charging protection circuit 16, so that the driver controls the main control switch to turn circuit off to stop charging.

The charging protection circuit 16 of the second embodiment can also determine whether the battery is fully charged. When all the batteries are fully charged, the charging protection circuit 16 sends a notification signal to the controller 10 to cause the controller 10 to send the cut-off signal to the driver, thereby causing the driver to control the main control switch to stop the charging mode, completing the charging process of battery pack 100. Therefore, the charging process prevents the battery from overcharging, and the safety and reliability of the charging process are improved.

The charging circuit of the second embodiment sends the notification signal to the controller 10 when the voltage of each battery detected by the charging protection circuit 16 exceeds the predetermined voltage value (the battery is fully charged), the controller 10 sends the control signal to the driver according to the notification signal, so that the driver controls the main control switch to stop the charging mode, thereby preventing the battery from overcharging, and improving the safety and reliability of the charging process.

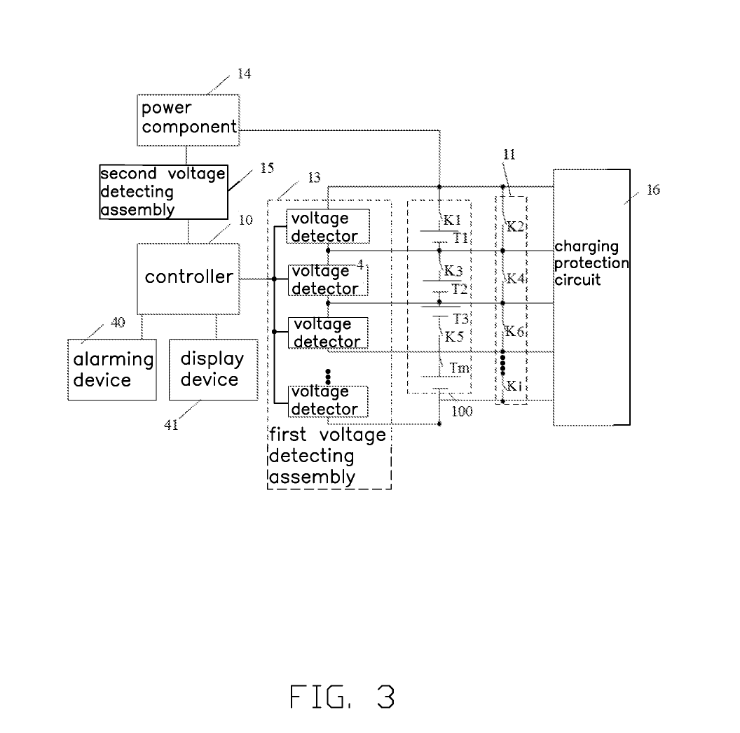

FIG. 3 shows a block diagram of a third embodiment of a charging circuit. FIG. 3 differs from FIG. 3 in that the charging circuit of FIG. 3 further includes an alarm device 40 and/or display device 41.

Specifically, the alarm device 40 is electrically connected to the controller 10.

In one embodiment, the controller 10 is further configured to send a signal to the alarm device 40 when the charging current exceeds a predetermined current or the detected battery voltage exceeds the predetermined voltage value, and the alarm device 40 is configured to issue an alarm when receiving the signal. The alarm device 40 can be a buzzer, an audible, a visual alarm or an audible and visual alarm, which can emit light and/or sound.

The display device 41 is electrically connected to the controller 10.

In one embodiment, the controller 10 is further configured to send a prompting information to the display device 41 when the charging current exceeds the predetermined current or the detected battery voltage exceeds the predetermined voltage value, and the display device 41 is configured to display the prompting information to prompt the user that the charging current is excessive or the battery is fully charged.

The charging circuit of the fourth embodiment alarms or displays the prompting information through the alarm device 40 or the display device 41 when the charging current exceeds the predetermined current or the detected battery voltage exceeds the predetermined voltage value, to prompt the user to take any necessary measures. Therefore, the safety and reliability of the charging process is further improved.

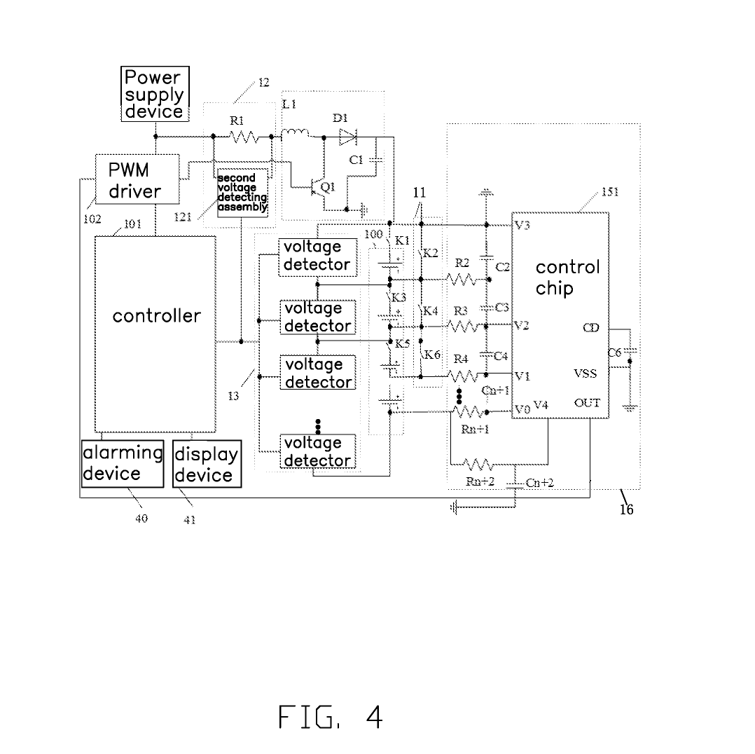

FIG. 4 shows a circuit diagram of a fourth embodiment of a charging circuit. The difference between FIG. 3 and FIG. 4 is that FIG. 4 provides a specific circuit diagram for implementing the inventive concept shown in FIG. 3.

Specifically, in the fourth embodiment, the charging circuit includes a controller 101 and a PWM driver 102. The controller 101 electrically connects to the PWM driver 102, a detecting assembly 12, a first detecting assembly 13, the switching assembly 11, and the charging protection circuit 16.

The first detecting assembly 13 includes voltage detectors of the same number as the number of batteries. Each voltage detector is electrically connected to the positive and negative poles of its corresponding battery for real time detecting the voltage of the corresponding battery.

In the switching assembly 11, the number of batteries and the number of switches satisfy the formula N>=2M, where M>=2. M is the number of batteries, and N is the number of switches. The plurality of switches in switching assembly 11 can stop charging batteries according to requirements, thereby fully charged batteries are protected.

The controller 101 can stop charging a certain battery by disconnecting a corresponding switch of the battery when the voltage of the battery detected by the first voltage detecting assembly 13 reaches the predetermined threshold value.

The controller 101 can be a Microcontroller Unit (MCU). The controller 101 sends a control signal to the PWM driver 102 when the charging current of the batter pack 100 exceeds the predetermined current or the detected voltage value of each battery exceeds the predetermined voltage value. The PWM drive 102 sends disconnecting signal to the main control switch according to the control signal, and the main control switch disconnects the charging path between a power supply device and the battery pack 100. Since each battery in series supplies a voltage signal to the controller 101, when all the batteries are fully charged during the charging process, the controller 101 sends a control signal to the PWM driver 102, and the PWM driver 102 sends a disconnecting signal to the main control switch, so that the main control switch stops the charging mode, thereby preventing batteries from overcharging and improving the safety and reliability of the charging process. At the same time, when the charging current exceeds the preset current, the controller 101 also sends the control signal to the PWM driver 102, and the PWM driver 102 sends the disconnecting signal to the main control switch, and the main control switch stops the charging mode to prevent an overcurrent to the battery.

The detecting assembly 12 includes a second voltage detecting assembly 121 and a power component. The second voltage detecting assembly 121 functions as a voltage detector, and the power component can be a first resistor R1. A terminal of the first resistor R1 electrically connects to a terminal of the second voltage detecting assembly 121, the PWM driver 102, and a charging interface. Another terminal of the first resistor R1 electrically connects to another terminal of the second voltage assembly 121 and the main control switch.

In the fourth embodiment, the battery can be charged by using a power supply device with a USB interface. The second voltage detecting assembly 121 detects a voltage across the first resistor R1, and sends the detected voltage to the controller 101. The controller 101 calculates a charging current of the battery pack 100 according to the voltage across the resistor R1 and the resistance of the first resistor R1.

The main control switch includes an inductor L1, a diode D1, a triode Q1, and a first capacitor C1. A terminal of the inductor L1 is connected to the first resistor R1, another terminal of the inductor L1 is connected to the anode of the diode D1, and the cathode of the diode D1 is grounded through the first capacitor C1. The base of the triode Q1 is electrically connected to the PWM driver 102, the emitter of the triode Q1 is grounded, and the collector of the triode Q1 is connected to the anode of the diode D1.

The fourth embodiment limits the charging current through the diode D1, protects the charging circuit of the battery, prevents the battery from being reversely connected, and starts and stops the charging mode by connecting and disconnecting the triode Q1. When the triode Q1 is connected, the charging current flows directly to the ground line, so charging stopped. When the triode Q1 is disconnected, the charging current flows directly into a corresponding battery in the battery pack 100 through the diode D1, and the charging circuit enters the charging mode. In other embodiments, the triode Q1 can be switching elements, such as transistors.

Referring to FIG. 4, the charging protection circuit 16 includes (n+1) resistors, (n+1) capacitors, and a control chip 151. The (n+1) resistors are followed by a second resistor R2, a third resistor R3, to an (n+2)th resistor Rn+2. The (n+1) capacitors are followed by a second capacitor C2, a third capacitor C3, to an (n+2)th capacitor Cn+2. When i<n−1, a terminal of the ith resistor, which is marked as Ri, is electrically connected between an (i−1)th battery and an ith battery, and another terminal of the ith resistor Ri is connected to a pin of the control chip 151. When i=n+1, a terminal of the ith resistor, which is marked as Rn+1, is electrically connected to the negative pole of the nth battery, and another terminal of the ith resistor Rn+1 is connected to a pin of the control chip 151. When i=n+2, a terminal of the ith resistor Rn+2 is electrically connected to the negative pole of the nth battery, and another terminal the ith resistor Rn+2 is connected to a pin of the control chip 151, where 2≤i≤n+2. A terminal of the second capacitor C2 connects to the other terminal of the second resistor, and another terminal of the second capacitor C2 is grounded. When 2<i<n+2, the ith capacitor Ci is connected between the ith resistor Ri and the (i+1)th resistor Ri+1, and is connected to the control chip 151. When i=n+2, a terminal of the ith capacitor Ci connects to the terminal of the ith resistor Ri connected to the control chip 151, and another terminal of ith capacitor Ci is grounded. The n is an integer greater than or equal to 2. The control chip 151 further includes a pin CD and a pin VSS. A capacitor C6 is connected between the pin CD and the pin VSS. The pin CD of the control chip 151 is grounded through the capacitor C6. Different resistors are connected to the control chip 151 with different pins.

The control chip 151 has separate pins, the positive and negative poles of each battery connect to the separate pins through corresponding resistors. When each battery is fully charged, the control chip 151 sends a notification signal to the controller 101 through the output pin OUT, and the controller 101 sends a control signal to the PWM driver 101, and then the PWM driver 102 sends a disconnecting signal to the main control switch, so that the main control switch turns off from the charging mode to complete the charging process of all batteries, thereby preventing batteries from overcharging and improving the safety and reliability of the charging process.

The following describes in detail the charging process of the charging circuit and its process of preventing overcharging and overcurrent supply.

The second voltage detecting component 121 detects the voltage across the first resistor R1 of the power component. The voltage detector in the first voltage detecting assembly 13 detects the voltage of each battery in the battery pack 100. The controller 101 calculates the charging current of the charging path between the power supply device and the battery pack 100 according to the voltage across the first resistor R1 and the resistance of the first resistor R1. When the charging current exceeds the predetermined current or the voltage of each battery detected by the first voltage detecting assembly 13 exceeds the predetermined voltage value, the controller 101 sends a control signal to the PWM driver 102. The PWM driver 102 sends a disconnecting signal to the triode Q1 of the main control switch according to the control signal, then the triode Q1 is connected, and the charging current flows directly to the ground, so that the charging path between the power supply device and the battery pack 100 is disconnected, and the charging is stopped. Therefore, batteries are prevented from overcharging during charging process, and the safety and reliability of the charging process is improved. Since the charging current flows directly to the ground, the charging path between the power supply device and the battery pack 100 is disconnected, the batteries are prevented from overcurrent supply.

Additionally, the charging protection circuit 16 detects the voltage of each battery in the battery pack 100. When the detected voltage value of each battery exceeds the predetermined voltage value, the charging protection circuit 16 sends the notification signal to the controller 101, and the controller 101 sends the control signal to the PWM driver 102 according to the notification signal. The PWM driver 102 sends the disconnecting signal to the triode Q1 of the main control switch according to the control signal, then the triode Q1 is connected, so that the charging path between the power supply device and the battery pack 100 is disconnected. Therefore, batteries are prevented from overcharging during the charging process, and the safety and reliability of the charging process is improved.

Additionally, by switching between the plurality of switches in the switching assembly 11, the number of batteries in charging can be flexibly adjusted according to actual needs. For example, if the switch K1 is disconnected and K2 is connected, other batteries except the first battery can be charged. If the switch K1 is connected and K2 is disconnected, the first battery can be charged.

Additionally, when the charging current exceeds the predetermined current or the detected voltage value of each battery exceeds the predetermined voltage value, the controller 101 sends the alarm signal to the alarm device 40. The alarm device 40 performs an alarm according to the alarm signal. For example, the alarm device 40 can emit light or sound to prompt the user to take any necessary measures, so that the safety and reliability of the charging process is improved.

Additionally, when the charging current exceeds the predetermined current or the detected voltage value of each battery exceeds the predetermined voltage value, the controller 101 sends the prompting information to the display device 41. The display device 41 displays the prompting information, such as an overcurrent prompting information or fully charged prompting information, to prompt the user to take any necessary measures, so that the safety and reliability of the charging process is improved.

According to the illustrated embodiments, the present disclosure further provides a charging device for batteries in series. The charging device includes charging circuits described in above embodiments.

In summary, the charging circuit and device for batteries in series provided by the present disclosure detects the voltage of each battery in the battery pack 100 through the first voltage detecting assembly 13. When the voltage of any battery reaches the predetermined threshold value, charging of the battery is stopped by the switch corresponding to the battery, thereby preventing the overcharging or overcurrent supply during the charging process of the battery, the safety and reliability of the charging process are improved. Using the switching assembly 11, the number of batteries in charging can be flexibly changed according to actual needs, and the circuit structure is simple and the cost is low.

The present disclosure further provides a charging method. The charging method may include at least the following steps:

During charging, a voltage of each battery in a battery pack is detected, and the battery pack includes at least two batteries connected in series with each other;

If a detected voltage exceeds a predetermined threshold value, charging the battery corresponding to the excessive voltage is stopped.

Alternatively, each of the batteries in the battery pack is provided with corresponding switches, and the switches include a first switch and a second switch. A pole of the first switch is connected to a pole of the battery, another pole of the first switch is connected to a pole of the second switch, and another pole of the second switch is connected to another pole of the battery. The step of stopping charging the battery corresponding to the voltage value may include at least the following steps:

The first switch corresponding to the battery is disconnected, and the second switch corresponding to the battery is connected.

Alternatively, the method may include at least the following steps:

If the voltages of all the batteries in the battery pack reach the predetermined threshold value, the charging the battery pack is stopped.

Alternatively, the method may include at least the following steps:

Obtaining a shutdown signal fed back by a charging protection circuit corresponding to the battery pack;

After receiving the shutdown signal, stop charging the battery pack.

Alternatively, each of the batteries in the battery pack is provided with corresponding switches, and the switches include a first switch and a second switch. A pole of the first switch is connected to a pole of the battery, another pole of the first switch is connected to a pole of the second switch, and another pole of the second switch is connected to another pole of the battery. The method may include at least the following steps:

Each battery is controlled to be powered through the switches.

The foregoing method can be used in the controllers described in the illustrated embodiments, and because implementation details are similar to those of the controllers described in the illustrated embodiments, there is no need to repeat.

The present disclosure further provides a charging device, the charging device executes the charging method, and includes a processor. The processor is configured to:

Obtain the voltage of each battery in a battery pack during charging, and the battery pack includes at least two batteries connected in series with each other;

If a detected voltage exceeds a predetermined threshold value, charging the battery corresponding to the excessive voltage is stopped.

Alternatively, each of the batteries in the battery pack is provided with corresponding switches, and the switches include a first switch and a second switch. A pole of the first switch is connected to a pole of the battery, another pole of the first switch is connected to a pole of the second switch, and another pole of the second switch is connected to another pole of the battery. The step of stopping charging the battery corresponding to the voltage value may include at least the following steps:

The first switch corresponding to the battery is disconnected, and the second switch corresponding to the battery is connected.

Alternatively, if the voltages of all the batteries in the battery pack reach the predetermined threshold value, the charging of the battery pack is stopped.

Alternatively, the method may include at least the following steps:

Obtaining a shutdown signal fed back by a charging protection circuit corresponding to the battery pack;

Charging of the battery pack is stopped according to the shutdown signal.

Alternatively, each of the batteries in the battery pack is provided with corresponding switches, and the switches include a first switch and a second switch. A pole of the first switch is connected to a pole of the battery, another pole of the first switch is connected to a pole of the second switch, and another pole of the second switch is connected to another pole of the battery. The method may include at least the following steps

Each battery is controlled to be powered through the corresponding switches.

In others implementations, the charging device further includes a storage. The storage stores at least one program instruction, and the processor implements the above functions by loading and executing the at least one program instruction.

Additionally, the present disclosure further provides a computer storage media having stored therein at least one program instruction. The at least one program instruction is loaded and executed by the processor to implement the charging method described above.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A charging circuit for a battery pack comprising a plurality of battery cells connected in series, comprising:
a controller;
a first voltage detecting assembly; and
a switching assembly comprising a plurality of switches corresponding to each battery cell;
wherein the first voltage detecting assembly is electrically connected to the battery pack and the controller, and is configured to detect a voltage of each battery cell in the battery pack, and sends the voltage of each battery cell to the controller;
when a detected voltage of a battery cell reaches a predetermined threshold value, the controller controls a switch corresponding to the battery cell to stop charging the battery cell.

2. The charging circuit of claim 1, wherein the controller is further configured to control whether each battery cell is powered through the switches corresponding to the battery cell.

3. The charging circuit of claim 1, wherein the switches corresponding to each battery cell comprises:
a first switch and a second switch, a pole of the first switch connects to a pole of the battery, another pole of the first switch connects to a pole of the second switch, another pole of the second switch connects to another pole of the battery.

4. The charging circuit of claim 3, wherein:
when the detected voltage of a battery cell reaches the predetermined threshold value, the controller disconnects the first switch and connects the second switch;
before the voltage of the battery cell reaches the predetermined threshold value, the controller connects the first switch and disconnects the second switch.

5. The charging circuit of claim 1, wherein the charging circuit further comprises a driving circuit electrically connected to the controller;
when the voltage of each battery cell in the battery pack reaches the predetermined threshold value, the controller stops charging the battery pack by turning off an external power source through the driving circuit.

6. The charging circuit of claim 5, wherein the driving circuit comprises a driver and a main control switch, a terminal of the driver connects to the controller, another terminal of the driver connects to a terminal of the main control switch, another terminal of the main control switch electrically connects to the battery pack.

7. The charging circuit of claim 6, wherein the main control switch comprises an inductor, a diode, a triode, and a first capacitor, a terminal of the inductor connects to the driver, another terminal of the inductor connects to the anode of the diode, and the cathode of the diode is grounded through the first capacitor, the cathode of the diode connects to a terminal of the battery pack, the base of the triode electrically connects the driver, the emitter of the triode is grounded, and the collector of the triode connects the anode of the diode.

8. The charging circuit of claim 6, wherein the driving circuit comprises:
a power component; and
a second voltage detecting assembly for detecting the voltage of the power component; wherein the second voltage detecting assembly electrically connects to the controller;
when a voltage value detected by the second voltage detecting assembly reaches a second predetermined threshold value, or the voltage value represents a charging current flowing through the power component exceeding a predetermined current, the controller turns off the external power source to stop charging the battery pack.

9. The charging circuit of claim 8, wherein a terminal of the power component connects to a charging interface, and another terminal of the power component connects to the inductor, the second voltage detecting assembly connects to both terminal of the power component.

10. The charging circuit of claim 1, wherein the charging circuit further comprises an alarm device electrically connected to the controller;
the controller controls the alarm device to cause an alarm when a voltage of a battery cell in the battery pack exceeds the predetermined threshold value.

11. The charging circuit of claim 1, wherein the charging circuit further comprises a di splay device electrically connected to the controller;
the controller controls the display device to display prompting information when a voltage of a battery in the battery pack exceeds the predetermined threshold value.

12. The charging circuit of claim 1, wherein the charging circuit further comprises a charging protection circuit, the charging protection circuit electrically connects to the controller and the battery pack;
the charging protection circuit is configured to send a control signal to the controller when the battery pack fails;
the controller stops charging the battery pack according to the control signal.

13. The charging circuit of claim 11, wherein the battery pack comprises n batteries cells, which are sequentially a first battery cell, a second battery cell to a nth battery cell; the charging protection circuit comprises (n+1) resistors, (n+1) capacitors, and a control chip;
the (n+1) resistors are followed by a second resistor, a third resistor to an (n+2)th resistor; the (n+1) capacitors are followed by a second capacitor, a third capacitor to an (n+2)th capacitor;
when i<n−1, a terminal of the ith resistor Ri is electrically connected between a (i−1)th battery and an ith battery, and another terminal is connected to a pin of the control chip;
when i=n+1, a terminal of the ith resistor Rn+1 is electrically connected to the negative pole of the nth battery, and another terminal is connected to a pin of the control chip;
when i=n+2, a terminal of the ith resistor Rn+2 is electrically connected to the negative pole of the nth battery, and another terminal is connected to a pin of the control chip;
where 2≤i≤n+2;
a terminal of the second capacitor connects to a terminal of the second resistor, and another terminal of the second capacitor is grounded;
when 2<i<n+2, the ith capacitor is connected between the ith resistor and the (i+1)th resistor, and is connected to the control chip;
when i=n+2, a terminal of the ith capacitor connects to the terminal of the ith resistor connected to the control chip, and another terminal is grounded.

14. A charging device, a charging circuit is implemented in the charging device, wherein the charging circuit comprising:
a controller,
a first voltage detecting assembly, and
a switching assembly,
the first voltage detecting assembly electrically connects to a battery pack and the controller, and is configured to detect a voltage of each battery cell in the battery pack, and sends the voltage of each battery cell to the controller;
the battery pack comprises at least two battery cells connected in series with each other;
the switching assembly comprises switches corresponding to each battery cell;
when a detected voltage of a battery cell reaches a predetermined threshold value, the controller controls the switches corresponding to the battery cell to stop charging the battery cell.

15. A charging method, wherein the method comprising:
a voltage of each battery cell in a battery pack is detected during charging process, and the battery pack comprises at least two batteries connected in series with each other;
if a detected voltage exceeds a predetermined threshold value, charging of the battery corresponding to the voltage is stopped.

16. The charging method of claim 15, wherein each of the battery cells in the battery pack is provided with corresponding switches, and the corresponding switches include a first switch and a second switch, a pole of the first switch is connected to a pole of the battery, another pole of the first switch is connected to a pole of the second switch, and another pole of the second switch is connected to another pole of the battery; the step of stopping charging the battery cell corresponding to the voltage value comprises:
the first switch corresponding to the battery cell is controlled to be disconnected, and the second switch corresponding to the battery cell is controlled to be connected.

17. The charging method of claim 15, wherein the method further comprises:
if the detected voltage of each battery cell in the battery pack reaches the predetermined threshold value, the charging of the battery pack is stopped.

18. The charging method of claim 15, wherein the method further comprises:
a shutdown signal fed back by a charging protection circuit corresponding to the battery pack is obtained;
charging of the battery pack is stopped according to the shutdown signal.

19. The charging method of claim 15, wherein each of the battery cells in the battery pack is provided with corresponding switches, and the corresponding switches include a first switch and a second switch, a pole of the first switch is connected to a pole of the battery, another pole of the first switch is connected to a pole of the second switch, and another pole of the second switch is connected to another pole of the battery; the method further comprises:
each battery cell is controlled to be powered through the corresponding switches.
